(19) United States
(12) Patent Application Publication
(10) Pub. No.: US 2025/0147118 A1
(43) Pub. Date: May 8, 2025

(54) APPARATUS FOR MANAGING BATTERY AND METHOD THEREOF

(71) Applicants: HYUNDAI MOTOR COMPANY, SEOUL (KR); KIA CORPORATION, SEOUL (KR)

(72) Inventor: Yo Han BAEK, Anyang-si (KR)

(21) Appl. No.: 18/672,229

(22) Filed: May 23, 2024

(30) Foreign Application Priority Data
Nov. 6, 2023 (KR) 10-2023-0151990

(51) Int. Cl. G01R 31/396; G01R 31/367; G01R 31/3842; G01R 31/389; G01R 31/392

(52) U.S. Cl. CPC G01R 31/396; G01R 31/367; G01R 31/3842; G01R 31/389; G01R 31/392

(57) ABSTRACT

Disclosed are an apparatus and method for managing a battery. The apparatus includes a battery, a voltage sensor that measures a voltage of the battery, and a processor. The processor determines an abnormal state of the battery during a first diagnosis period, determines a diagnostic profile corresponding to a type of the abnormal state of the battery based on the detected abnormal state of the battery in the first diagnosis, controls a diagnostic condition of the battery based on the diagnostic profile, and re-diagnoses an abnormal state of the battery during a second diagnosis period while the diagnostic condition is controlled based on the diagnostic profile.

### CROSS-REFERENCE TO RELATED APPLICATION

This application claims the benefit of priority to Korean Patent Application No. 10-2023-0151990, filed in the Korean Intellectual Property Office on Nov. 6, 2023, the entire contents of which are incorporated herein by reference.

### TECHNICAL FIELD

The present disclosure relates to an apparatus for managing a battery and a method thereof, and more particularly, to a technology for determining an abnormal state of a battery.

### BACKGROUND

Due to the diversity of electronic devices, the field of use of batteries has increased, and recently, the use of batteries has increased as electric vehicles such as electric vehicles or hybrid vehicles are introduced.

Defects may occur in a battery due to deterioration caused by use or shock from the outside. Because battery defects cause risks such as fire in addition to simple battery performance degradation, the importance of technology capable of detecting battery defects in advance has also emerged.

Experts at a vehicle service center and the like may determine whether the battery is defective, but visiting a service center to determine defects of a battery may cause considerable inconvenience to users.

Vehicles with internal combustion engines use diagnostic trouble codes (DTC) to independently determine vehicle condition abnormalities, but a scheme of determining in advance the occurrence of defects in a battery mounted on an electric vehicle has not been systematically established.

### SUMMARY

The present disclosure has been made to solve the above-mentioned problems occurring in the prior art while advantages achieved by the prior art are maintained intact.

An aspect of the present disclosure provides an apparatus and method for battery management capable of accurately determining whether the battery mounted on a vehicle is defective.

In addition, an aspect of the present disclosure provides an apparatus and method for battery management capable of accurately determining the internal resistance of the battery.

In addition, an aspect of the present disclosure provides an apparatus and method for battery management capable of accurately determining the state of health of the battery.

In addition, an aspect of the present disclosure provides an apparatus and method for battery management capable of accurately determining the leakage current of the battery.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for battery management includes the battery, a voltage sensor that measures a voltage of the battery, and a processor. The processor determines an abnormal state of the battery during a first diagnosis period, determines a diagnostic profile corresponding to a type of the abnormal state of the battery based on the detected abnormal state of the battery in a first diagnosis, controls a diagnostic condition of the battery based on the diagnostic profile, and re-diagnoses the abnormal state of the battery during a second diagnosis period while the diagnostic condition is controlled based on the diagnostic profile.

According to an embodiment, the processor may detect at least one of an increase in an internal resistance of the battery, an increase in a leakage current of the battery, or a decrease in a state of health of the battery during the first diagnosis period.

According to an embodiment, the processor may monitor a fast charging attempt of the battery based on the detection of the increase in the internal resistance of the battery as a determination result in the first diagnosis period, and control the diagnostic condition when the fast charging attempt is present.

According to an embodiment, the processor may control the diagnostic condition to increase a change rate of a reference current followed by the battery based on the fast charging attempt.

According to an embodiment, the processor may control the diagnostic condition to inactivate a cell balancing operation of the battery based on the detection of the increase in the leakage current of the battery as a determination result in the first diagnosis period.

According to an embodiment, the processor may monitor a slow charging attempt of the battery based on the detection of the decrease in the state of health of the battery as a determination result in the first diagnosis period, and control the diagnostic condition based on the slow charging attempt.

According to an embodiment, the processor may control the diagnostic condition to charge the battery at a constant current based on the slow charging attempt.

According to an embodiment, the processor may determine a minimum charging current value based on a maximum charging power of a slow charger and a fully charged battery voltage, and control slow charging based on the minimum charging current value.

According to an embodiment, the processor may confirm a first measurement value indicating a degree of the abnormal state of the battery in the first diagnosis period, confirm a second measurement value indicating the degree of the abnormal state of the battery in the second diagnosis period, and determine a defective state of the battery based on magnitudes of the first measurement value and the second measurement value.

According to an embodiment, the processor may determine the battery to be in a false defect state based on a magnitude ratio of the second measurement value to the first measurement value exceeding a specified range, and count a number of times the battery is determined to be in the false defect state, and guide a precise diagnosis of the battery based on that the counted number of times the false defect state is greater than or equal to a threshold number.

According to another aspect of the present disclosure, a method of managing a battery includes performing, by the processor, a first diagnosis to determine an abnormal state of the battery, determining, by the processor, a diagnostic profile corresponding to a type of the abnormal state of the battery based on a detected abnormal state of the battery in the performing of the first diagnosis, controlling a diagnostic condition of the battery based on the diagnostic profile, and performing a second diagnosis of re-diagnosing the abnormal state of the battery while a diagnostic condition of the battery is controlled based on the diagnostic profile.

According to an embodiment, the performing of the first diagnosis may include detecting at least one of an increase in an internal resistance of the battery, an increase in a leakage current of the battery, or a decrease in a state of health of the battery.

According to an embodiment, the controlling of the diagnostic condition of the battery may include increasing a change rate of a reference current followed by the battery in a fast charging period based on the detection of the increase in the internal resistance of the battery through the first diagnosis.

According to an embodiment, the controlling of the diagnostic condition of the battery may include inactivating a cell balancing operation of the battery based on the detection of the increase in the leakage current of the battery through the first diagnosis.

According to an embodiment, the controlling of the diagnostic condition of the battery may include charging the battery at a constant current in a slow charging period of the battery based on the detection of the decrease in the state of health of the battery through the first diagnosis.

According to an embodiment, the controlling of the diagnostic condition of the battery may include monitoring a driving state of a vehicle equipped with the battery, and controlling the diagnostic condition of the battery based on detection of the driving state of the vehicle corresponding to the diagnostic profile.

According to an embodiment, the performing of the second diagnosis may further include confirming a first measurement value indicating a degree of the abnormal state of the battery based on the first diagnosis, confirming a second measurement value indicating the degree of the abnormal state of the battery in the second diagnosis, and determining a defective state of the battery based on magnitudes of the first measurement value and the second measurement value.

According to an embodiment, the method may further include determining the battery to be in a false defect state based on a magnitude ratio of the second measurement value to the first measurement value exceeding a specified range, and counting a number of times the battery is determined to be in the false defect state, and guiding a precise diagnosis of the battery based on that the counted number of times the false defect state is greater than or equal to a threshold number.

According to an embodiment, the method may further include restricting entry into the second diagnosis when the first measurement value has a magnitude that cannot determine a risk of the battery.

According to an embodiment, the method may further include confirming with a user of the vehicle whether the second diagnosis is entered based on that the first measurement value is greater than or equal to a threshold value.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating the connection relationship of an apparatus for managing a battery according to an embodiment of the present disclosure;

FIG. 2 is a block diagram illustrating the configuration of an apparatus for managing a battery according to an embodiment of the present disclosure;

FIG. 3 is a flowchart illustrating a method of managing a battery according to an embodiment of the present disclosure;

FIG. 4 is a flowchart illustrating a method of controlling a diagnostic condition of a battery according to an embodiment of the present disclosure;

FIG. 5 is a flowchart illustrating a method of performing a second diagnosis according to a first embodiment of the present disclosure;

FIG. 6 is a diagram illustrating a reference current in a fast charging profile;

FIG. 7 is a diagram illustrating a diagnostic fast charging profile according to an embodiment of the present disclosure;

FIG. 8 is a flowchart illustrating a method of performing a second diagnosis according to a second embodiment of the present disclosure;

FIG. 9 is a flowchart illustrating a method of performing a second diagnosis according to a third embodiment of the present disclosure;

FIG. 10 is a flowchart illustrating a method of managing a battery according to another embodiment of the present disclosure;

FIG. 11 is a flowchart illustrating a method of managing a battery according to another embodiment of the present disclosure; and

FIG. 12 is a diagram illustrating a computing system according to an embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of the related known configuration or function will be omitted when it is determined that it interferes with the understanding of the embodiment of the present disclosure.

In describing the components of the embodiment according to the present disclosure, terms such as first, second, A, B, (a), (b), and the like may be used. These terms are merely intended to distinguish the components from other components, and the terms do not limit the nature, order or sequence of the components. Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

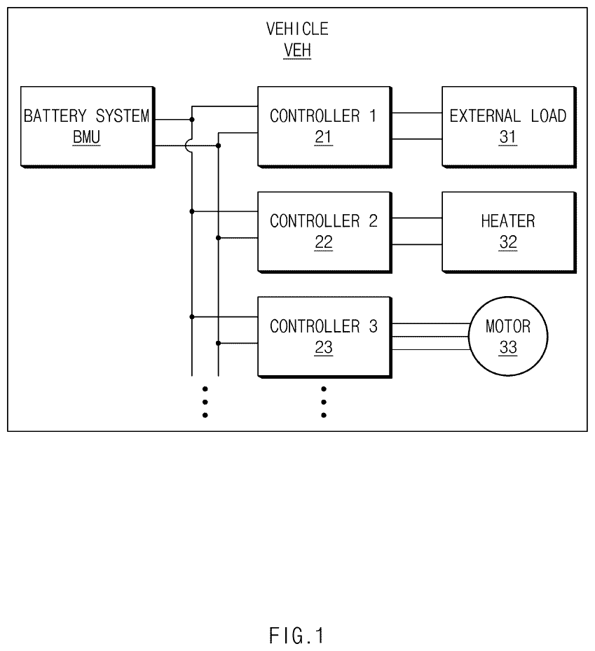

Hereinafter, embodiments of the present disclosure will be described in detail with reference to FIGS. 1 to 12.

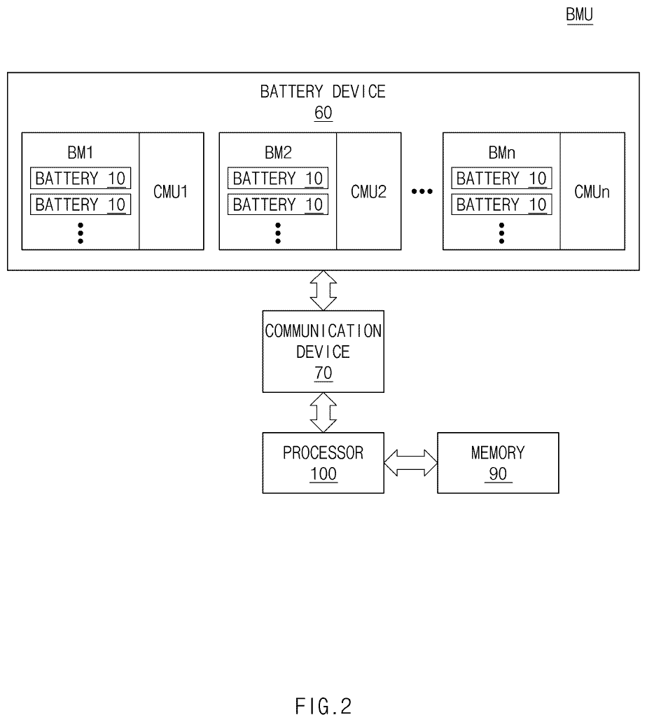

FIG. 1 is a block diagram illustrating the connection relationship of an apparatus for managing a battery according to an embodiment of the present disclosure. FIG. 2 is a block diagram illustrating the configuration of an apparatus for managing a battery according to an embodiment of the present disclosure.

Referring to FIG. 1, an apparatus for managing a battery BMU according to an embodiment of the present disclosure may be mounted on a vehicle VEH and provide a voltage to controllers 21, 22, and 23 within the vehicle. For example, the first controller 21 may provide a voltage to an external load 31. The second controller 22 may include a DC/DC converter for providing a voltage to a heater 32. The third controller 23 may include a DC/AC converter for providing a voltage to a motor 33 that drives the vehicle.

Referring to FIG. 2, the apparatus for managing a battery BMU according to an embodiment of the present disclosure may include a battery device 60, a communication device 70, sensor devices CMU1 to CMUn, and a processor 100.

The battery device 60 may include n (n being a natural number of 2 or more) battery modules BM1 to BMn. Each of the battery modules BM1 to BMn may include a plurality of batteries 10. Each of the batteries 10 may be referred to as a battery cell.

The sensor devices CMU1 to CMUn may be implemented as cell monitoring units with one-to-one correspondence to the battery modules BM1 to BMn. The first CMU CMU1 may sense the voltage of the first battery module BM1. In addition, the sensor devices CMU1 to CMUn may obtain battery state information. The battery state information may include at least one of the internal resistance of the battery 10, the leakage current of the battery 10, or the state of health (SOH) of the battery 10.

The communication device 70, which is for communication between the sensor devices CMU1 to CMUn and the processor 100, may be implemented with a wired or wireless communication device.

For example, the communication device 70 may support short-range communication by using at least one of Bluetooth™, radio frequency identification (RFID), infrared data association (IrDA), ultra wideband (UWB), ZigBee™, near field communication (NFC), Wireless-Fidelity (Wi-Fi), Wi-Fi Direct, and wireless universal serial bus (USB) technology.

In addition, when the processor 100 is located outside a vehicle, the communication device 70 may perform communication based on global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTEA), and the like.

The processor 100 may diagnose an abnormal state of at least one of the plurality of batteries 10. Hereinafter, the plurality of batteries 10 will be collectively referred to as the battery 10.

The processor 100 may perform a first diagnosis to obtain a first measurement value indicating the degree of an abnormal state of the battery 10. The first diagnosis may be performed using battery state information obtained while driving the vehicle VEH.

In addition, the processor 100 may perform a second diagnosis to obtain a second measurement value indicating the degree of an abnormal state of the battery 10. The second diagnosis may be used to measure the detected abnormal state more accurately when the abnormal state of the battery 10 is detected in the first diagnosis. To this end, the processor 100 may control the driving state of the vehicle VEH to more accurately determine the abnormal state of the battery 10. For example, the processor 100 may control the driving state of the vehicle VEH and determine the abnormal state of the battery 10 by applying a diagnostic profile. The details of the diagnostic profile will be described below.

The processor 100 may determine a defective state of the battery 10 based on the first measurement value and the second measurement value. For example, the processor 100 may determine that the battery 10 is defective based on the fact that the ratio between the first measurement value and the second measurement value is less than or equal to a specified level.

In addition, the processor 100 may determine whether the battery 10 is defective by comparing the second measurement value with a comparison value. The comparison value, which is preset, may comprise state information of the battery 10 in a normal state.

The processor 100 may receive battery state information from the sensor devices CMU1 to CMUn, or may obtain battery state information based on the voltage value or current value of the battery 10. The processor 100 may diagnose an abnormal state of the battery 10 based on the battery state information.

The processor 100 may determine an abnormal state of the battery 10 by comparing battery state information and reference battery state information. The reference battery state information may be preset. The state information of normal batteries of other vehicles may be collected as big data and may be set based on the collected big data.

The algorithm for operating the processor 100 may be stored in a memory 90. The memory 90 may include a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a dynamic random access memory (DRAM), a synchronous dynamic random access memory (SDRAM), a double date rate-SDRAM (DDR-SDRAM), and the like.

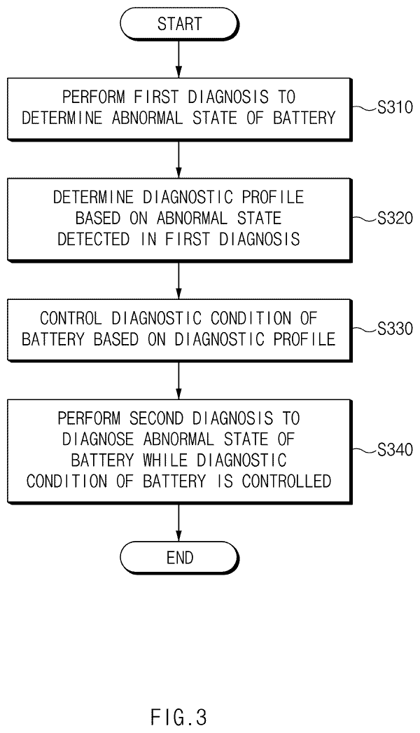

FIG. 3 is a flowchart illustrating a method of managing a battery according to an embodiment of the present disclosure. FIG. 3 mainly illustrates a method of determining an abnormal state of a battery. The procedure shown in FIG. 3 may be performed by the processor 100.

With reference to FIG. 3, a method of managing a battery according to an embodiment of the present disclosure will be described below.

In operation, at step S310, the processor 100 may perform a first diagnosis to determine an abnormal state of the battery 10.

The abnormal state of the battery 10 may be at least one of an increase in internal resistance of the battery 10, an increase in leakage current of the battery 10, or a decrease in SOH of the battery 10.

The processor 100 may determine an abnormal state of the battery 10 by comparing battery state information and reference state information. For example, the processor 100 may determine that the internal resistance of the battery 10 is increased based on the fact that the measured internal resistance value of the battery 10 is greater than or equal to a threshold resistance. In addition, the processor 100 may determine that the leakage current of the battery 10 is increased based on the fact that the measured leakage current of the battery 10 is greater than or equal to the threshold current. In addition, the processor 100 may determine that the SOH of the battery 10 is decreased based on the fact that the SOH measurement value of the battery 10 is less than or equal to a threshold SOH. In operation, at step S320, the processor 100 may determine a diagnostic profile corresponding to the type of the abnormal state of the battery 10 based on the abnormal state of the battery 10 detected in the first diagnosis.

For example, the processor 100 may determine a fast charging profile for diagnosis based on the increase in internal resistance of the battery 10 detected in the first diagnosis. The fast charging profile for diagnosis may be provided for adjusting the control condition of fast charging.

In addition, the processor 100 may determine a leakage current measurement profile for diagnosis of the battery 10 based on an increase in leakage current of the battery 10 detected in the first diagnosis. The diagnostic leakage current measurement profile may be used to adjust the control condition of leakage current measurement.

In addition, the processor 100 may determine a diagnostic slow charging profile based on a decrease in SOH of the battery 10 detected in the first diagnosis. The diagnostic slow charging profile may be used to adjust the control condition of slow charging.

In operation, at step S330, the processor 100 may control the diagnostic condition of the battery 10 based on the diagnostic profile.

For example, the processor 100 may control the fast charging condition by applying the diagnostic fast charging profile. The diagnostic fast charging profile may include an operation of increasing the change rate of the reference current followed by the battery 10 in the fast charging period.

In addition, the processor 100 may adjust the control condition for leakage current measurement by applying the diagnostic leakage current measurement profile. The diagnostic leakage current measurement profile may include an operation of inactivating a cell balancing function during the leakage current measurement period.

In addition, the processor 100 may adjust the control condition of slow charging by applying the diagnostic slow charging profile. The diagnostic slow charging profile may include an operation of charging the battery 10 with a constant current during the slow charging period.

In operation, at step S340, the processor 100 may perform a second diagnosis to diagnose an abnormal state of the battery 10 while the diagnostic condition of the battery 10 is controlled based on the diagnostic profile.

For example, the processor 100 may determine whether the internal resistance of the battery 10 is abnormal while the diagnostic fast charging profile is executed.

In addition, the processor 100 may determine an abnormal leakage current state of the battery 10 while the diagnostic leakage current measurement profile is executed.

In addition, the processor 100 may determine an SOH abnormal state of the battery 10 while the diagnostic slow charging profile is executed.

Among the procedures shown in FIG. 3, operation S330 may be performed when an event corresponding to the diagnostic profile is detected. The event may be determined based on monitoring the operating state of the vehicle VEH. The driving state of the vehicle may include a fast charging attempt of the vehicle VEH or a slow charging attempt of the vehicle VEH.

For example, based on the diagnostic fast charging profile determined at step S320, the processor 100 may monitor whether the vehicle VEH attempts fast charging. To this end, the processor 100 may monitor whether the vehicle VEH is connected to the connector of a fast charger. When the vehicle VEH attempts fast charging, the processor 100 may execute the diagnostic fast charging profile.

In addition, based on the diagnostic slow charging profile determined at step S320, the processor 100 may monitor whether the vehicle VEH attempts slow charging. To this end, the processor 100 may monitor whether the vehicle VEH is connected to the connector of a slow charger. When the vehicle VEH attempts slow charging, the processor 100 may execute the diagnostic slow charging profile.

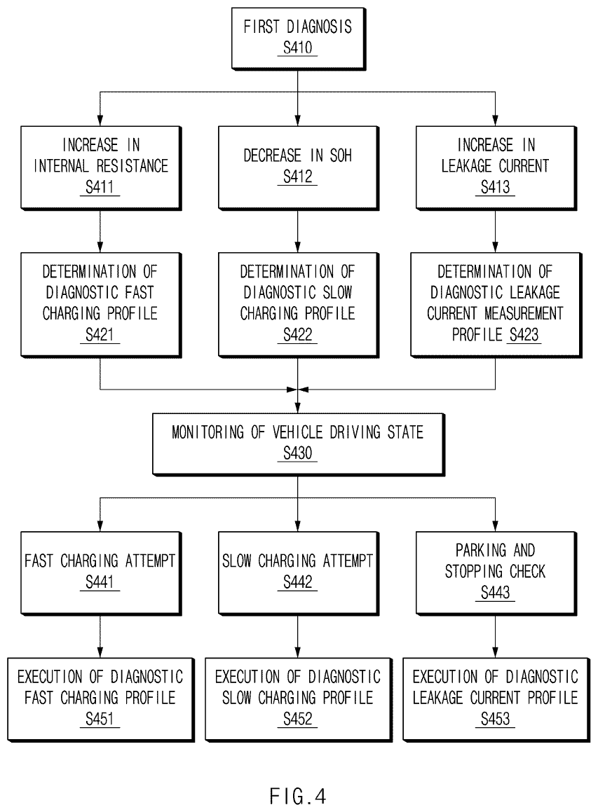

FIG. 4 is a flowchart illustrating a method of controlling a diagnostic condition of a battery according to an embodiment of the present disclosure. The procedures shown in FIG. 4 may be controlled by the processor 100. With reference to FIGS. 3 and 4, a method of controlling a diagnostic condition of a battery according to an embodiment of the present disclosure will be described below.

In step S410, the processor 100 may perform the first diagnosis. The processor 100 may determine at least one of an increase in internal resistance, a decrease in SOH, and an increase in leakage current through the first diagnosis.

In steps S411 and S421, the processor 100 may determine the diagnostic fast charging profile corresponding to an increase in internal resistance of the battery 10.

In steps S412 and S422, the processor 100 may determine the diagnostic slow charging profile corresponding to a decrease in SOH of the battery 10.

In steps S413 and S423, the processor 100 may determine the diagnostic leakage current measurement profile corresponding to an increase in leakage current of the battery 10.

In step S430, after the diagnostic profile is determined, the processor 100 may monitor the vehicle driving state. The processor 100 may monitor the vehicle driving state matching the diagnostic profile. For example, the processor 100 may monitor whether the vehicle VEH attempts fast charging corresponding to the determination of the diagnostic fast charging profile. In addition, the processor 100 may monitor whether the vehicle VEH attempts slow charging corresponding to the determination of the diagnostic slow charging profile.

In steps S441 and S451, the processor 100 may execute the diagnostic fast charging profile corresponding to the fast charging attempt.

In steps S442 and S452, the processor 100 may execute the diagnostic slow charging profile corresponding to the slow charging attempt.

In steps S443 and S453, the processor 100 may execute the diagnostic leakage current measurement profile corresponding to the vehicle VEH being in a parked or stopped state.

Hereinafter, a method of performing a second diagnosis according to an embodiment of the present disclosure will be described in detail.

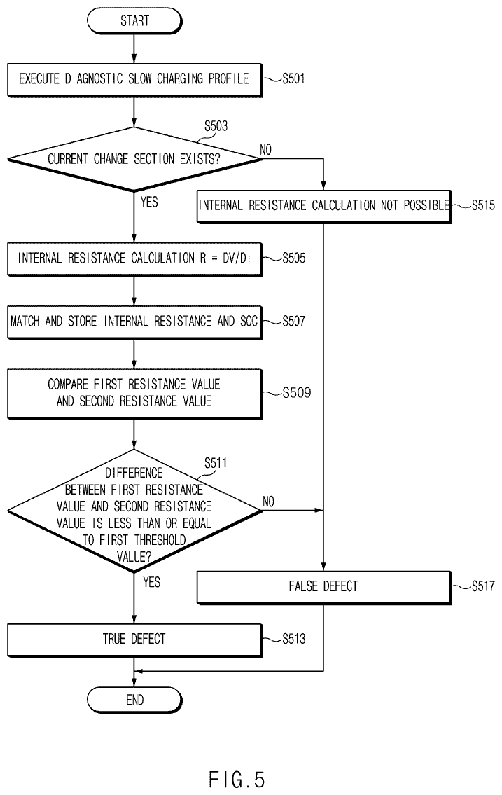

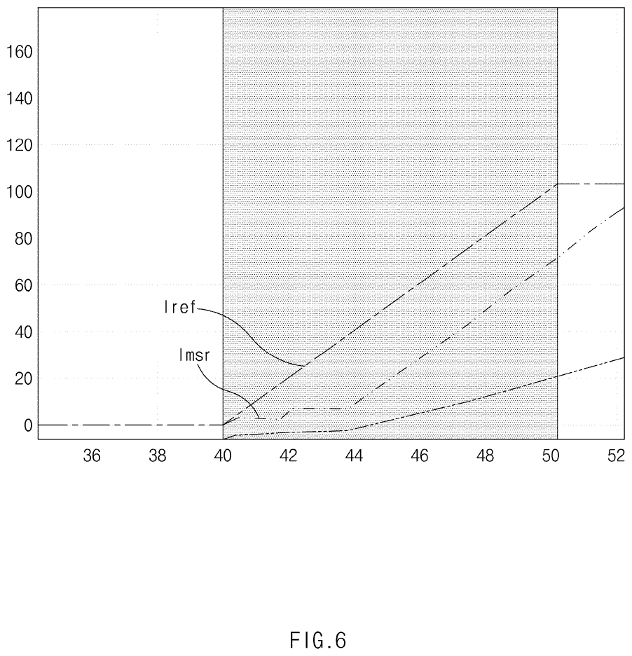

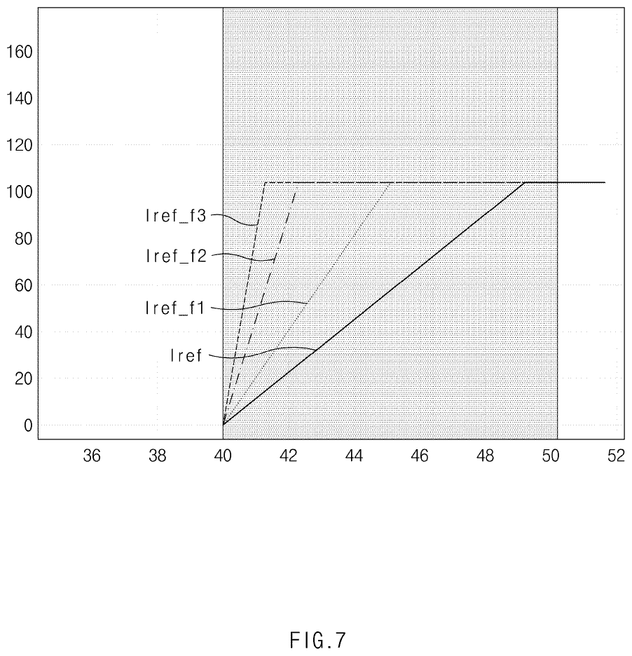

FIG. 5 is a flowchart illustrating a method of performing a second diagnosis according to a first embodiment of the present disclosure. FIG. 5 illustrates a method of determining an abnormal state of internal resistance of a battery by executing a diagnostic fast charging profile. The procedures shown in FIG. 5 may be controlled by a processor. FIG. 6 is a diagram illustrating a reference current in a fast charging profile. FIG. 7 is a diagram illustrating a diagnostic fast charging profile according to an embodiment of the present disclosure.

With reference to FIGS. 5 to 7, a method of determining an internal resistance abnormal state based on a diagnostic fast charging profile will be described in detail below.

In step S501, the processor 100 may execute a diagnostic fast charging profile. Step S501 may be step S451 shown in FIG. 4. The diagnostic fast charging profile will be described with reference to FIGS. 6 and 7 below.

Referring to FIG. 6, during the fast charging period, the battery 10 may be charged while estimating a reference current Iref representing a specified level of change rate. In FIG. 6, a measured current Imsr may mean the measured current of the battery 10 during the fast charging period.

When the diagnostic fast charging profile according to an embodiment of the present disclosure is executed, the processor 100 may provide a charger with one of a first diagnostic reference current Iref_f1, a second diagnostic reference current Iref_f2, or a third diagnostic reference currents Iref_f3 shown in FIG. 7. The diagnostic reference currents Iref_f1, Iref_f2, and Iref_f3 may be set to have a current change rate greater than that of the reference current Iref.

When the diagnostic fast charging profile is executed, the IR drop of the battery 10 may appear large and the open circuit voltage (OCV) appears small, so that it is possible to determine the internal resistance of the battery 10 more accurately.

In step S503, the processor 100 may monitor whether a current change section is detected.

In step S505, the processor 100 may calculate the internal series resistance of the battery 10 corresponding to the detected current change section. For example, the processor 100 may determine the internal resistance (R) based on the amount (dV) of change in voltage and the amount (dI) of change in current of the battery 10.

In step S507, the processor 100 may match the internal resistance and the remaining SOC of the battery 10 and store them in the memory 90.

In step S509, the processor 100 may compare the first resistance value and the second resistance value.

The first resistance value may be the internal resistance of the battery 10 measured in the first diagnosis, and may be an internal resistance measured to be greater than the threshold resistance value. The second resistance value may be measured in step S505.

In addition, step S509 may be performed after confirming the SOC stored in the memory 90. This is because the performance and state of the battery 10 may vary depending on the SOC, and the internal resistance may vary depending on the SOC.

Accordingly, the processor 100 may compare the first SOC of the battery 10 at the time point at which the first resistance value is measured and the second SOC of the battery 10 at the time point at which the second resistance value is measured, and when the first SOC is different from the second SOC, the processor 100 may skip procedures after step S509.

In steps S511 and S513, the processor 100 may determine whether the battery 10 is truly defective based on the fact that the difference between the first resistance value and the second resistance value is less than or equal to the first threshold value.

The difference between the first resistance value and the second resistance value may be determined based on the magnitude ratio between the first resistance value and the second resistance value. For example, the processor 100 may determine whether the battery 10 is truly defective based on the fact that the magnitude of the first resistance value compared to the second resistance value is within a first preset range.

In this specification, the true defect of the battery 10 may mean a defective state determined by combining the first diagnosis and the second diagnosis, and may mean that the battery 10 is in a defective state to the extent that a detailed diagnosis of the abnormal state of the battery 10 is required. For example, as shown in FIG. 5, when it is determined that the first resistance value and the second resistance value consistently indicate a defective state, the processor 100 may determine that the battery 10 is truly defective. In addition, in this specification, the fact that the battery 10 is in a defective state may mean that the battery 10 is in a truly defective state.

In steps S515 and S517, the processor 100 may determine that the internal series resistance of the battery 10 cannot be measured corresponding to the fact that there is no current change section. The processor 100 may determine that the battery 10 is in a false defect state corresponding to the fact that the internal series resistance of the battery 10 cannot be determined.

In addition, based on the fact that the difference between the first resistance value and the second resistance value is greater than the first threshold value in step S511, it may be determined that the battery 10 is in a false defect state.

In this specification, a false defect of the battery 10 may mean that the first resistance value and the second resistance value are not consistent, so the battery 10 cannot be determined to be defective.

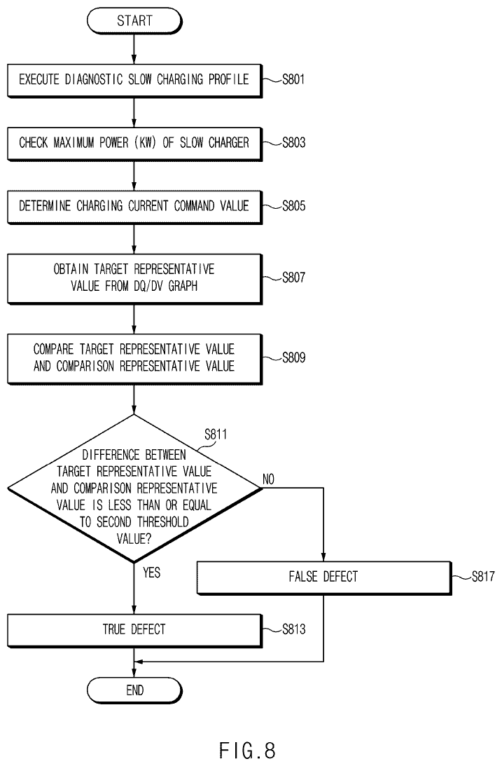

FIG. 8 is a flowchart illustrating a method of performing a second diagnosis according to a second embodiment of the present disclosure. FIG. 8 is a flowchart illustrating a method of determining the SOH abnormal state of a battery by executing a diagnostic slow charging profile. The procedures shown in FIG. 8 may be controlled by a processor.

With reference to FIG. 8, a method of determining the SOH abnormal state of a battery based on the diagnostic slow charging profile will be described below.

In step S801, the processor 100 may execute the diagnostic slow charging profile. Step S801 may be step S452 shown in FIG. 4.

In step S803, the processor 100 may check the maximum power of the slow charger.

In step S805, the processor 100 may calculate a charging current command value based on the maximum power of the slow charger. The charging current command value may mean a fixed current value for charging the battery 10 in the slow charging period.

The processor 100 may calculate the charging current command value based on the maximum charging power and the fully charged pack voltage. For example, the processor 100 may calculate the charging current command value as shown in following Equation 1.

$$Charging current command value = \frac{Maximum charging power}{Fully charged pack voltage} \qquad [ Equation 1 ]$$

In step S807, the processor 100 may obtain a target dQ/dV graph in the slow charging period and obtain a target representative value from the target dQ/dV graph.

The dQ/dV graph may mean the amount of change in power storage according to the amount of change in voltage, and may denote the voltage change characteristics in the slow charging period. According to an embodiment, because slow charging is performed using a charging current command value having a constant current value, the dQ/dV graph may be derived more accurately.

The target representative value may be an integral value of the target do/dV graph during the slow charging period. Alternatively, the target representative value may be the sum of the peaks of the target dQ/dV graph during the slow charging period, and the peak may mean the dQ/dV value at the point where the slope of the dQ/dV graph changes.

In step S809, the processor 100 may compare the target representative value with the comparison representative value.

The comparison representative value may be obtained by obtaining a comparison dQ/dV graph during the slow charging period of a normal battery and derived from the comparison dQ/dV graph. The comparison representative value may be an integral value of the comparison dQ/dV graph in the slow charging period. Alternatively, the comparison representative value may be the sum of the peaks of the comparison dQ/dV graph during the slow charging period.

In steps S811 and S813, it is possible to determine whether the battery 10 is truly defective based on the fact that the difference between the target representative value and the comparison representative value is less than or equal to the second threshold value.

The difference between the target representative value and the comparison representative value may be determined based on the magnitude ratio between the target representative value and the comparison representative value. For example, the processor 100 may determine whether the battery 10 is truly defective based on the fact that the magnitude of the target representative value compared to the comparison representative value is within a preset second range.

When the difference between the target representative value and the comparison representative value is greater than the second threshold value, in step S817, the processor 100 may determine that the battery 10 is falsely defective.

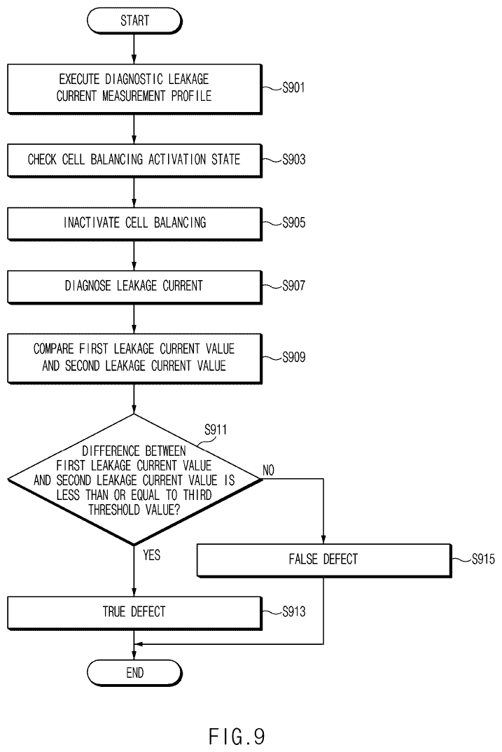

FIG. 9 is a flowchart illustrating a method of performing a second diagnosis according to a third embodiment of the present disclosure. FIG. 9 is a flowchart illustrating a method of determining an abnormal leakage current state of a battery by executing a diagnostic leakage current measurement profile. The procedures shown in FIG. 9 may be controlled by a processor.

With reference to FIG. 9, a method of determining an abnormal leakage current state of a battery based on a diagnostic leakage current measurement profile will be described below.

In step S901, the processor 100 may execute a diagnostic leakage current measurement profile. Step S901 may be step S453 shown in FIG. 4.

In step S903, the processor 100 may check a cell balancing activation state. Cell balancing may be an operation of improving the voltage difference between batteries 10. Alternatively, the cell balancing may be an operation of improving the voltage difference between the battery modules BM1 to BMn.

In step S905, the processor 100 may maintain a cell balancing inactivated state. Step S905 may include stopping cell balancing based on the fact that the cell balancing is activated in step S903.

In step S907, the processor 100 may determine the leakage current of the battery 10. Because the diagnostic leakage current measurement profile is executed based on the fact that the vehicle VEH is parked or stopped, the processor 100 may determine the leakage current while the voltage of the battery 10 is stable. In addition, because the processor 100 measures a leakage current while cell balancing of the battery 10 is inactivated, the failure to accurately measure a leakage current due to current consumed in cell balancing may be improved.

In step S909, the processor 100 may compare the first leakage current value and the second leakage current value.

The first leakage current value may be the leakage current value of the battery 10 measured in the first diagnosis, and may be measured above the threshold current. The second leakage current value may be measured in operation S907.

In steps S911 and S913, the processor 100 may determine whether the battery 10 is truly defective based on the fact that the difference between the first leakage current value and the second leakage current value is less than or equal to the third threshold value.

The difference between the first leakage current value and the second leakage current value may be determined based on the magnitude ratio between the first leakage current value and the second leakage current value. For example, the processor 100 may determine whether the battery 10 is truly defective based on the fact that the magnitude of the first leakage current value compared to the second leakage current value is within a specified range.

Based on the fact that the difference between the first leakage current value and the second leakage current value is greater than the third threshold value, in operation S915, the processor 100 may determine whether the battery 10 is falsely defective.

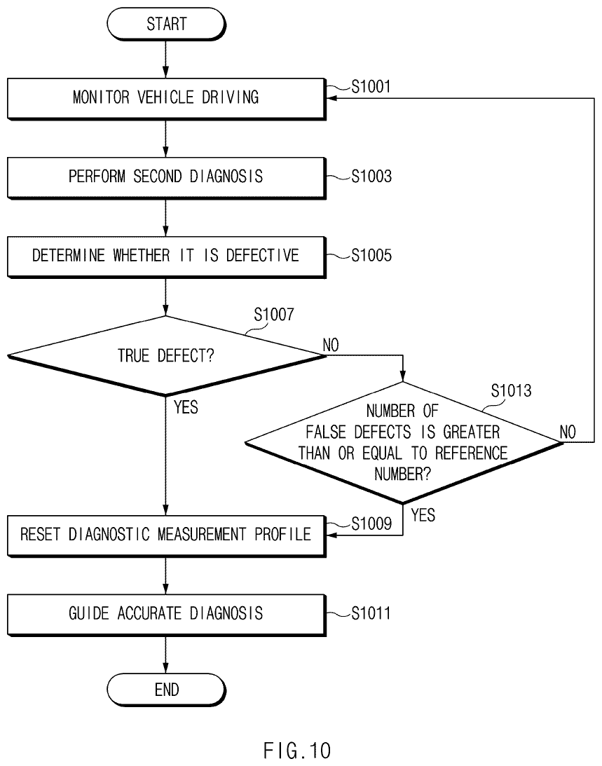

FIG. 10 is a flowchart illustrating a method of managing a battery according to another embodiment of the present disclosure. FIG. 10 illustrates a method of managing a defect of a battery based on the number of battery failure determinations, and may be procedures controlled by a processor.

Referring to FIG. 10, in step S1001, the processor 100 may monitor the vehicle driving state. Step S1001 may include monitoring battery state information and performing the first diagnosis of the battery 10 based on the battery state information.

In step S1003, the processor 100 may perform the second diagnosis. The second diagnosis may be a procedure performed after the first diagnosis is performed. The second diagnosis may be detecting one of an increase in internal resistance of the battery 10, an increase in leakage current of the battery 10, or a decrease in SOH of the battery 10.

In step S1005, the processor 100 may determine whether the battery 10 is defective. In step S1005, the processor 100 may determine whether the battery 10 is truly or falsely defective.

In steps S1007 and S1009, based on the fact that it is determined that the battery 10 is truly defective, the processor 100 may reset the diagnostic measurement profile. For example, step S1009 may include a procedure for resetting steps S421, S422, and S423 of determining diagnostic profiles shown in FIG. 4.

In step S1011, the processor 100 may guide a precise diagnosis of the battery 10 based on the fact that it is determined that the battery 10 is truly defective. The processor 100 may guide precise diagnosis of the battery 10 through a display or speaker in the vehicle VEH. The precise diagnosis of the battery 10 may mean requesting a professional company such as a service center to determine whether the battery 10 is defective.

In response to determining that the battery 10 is falsely defective in step S1007, in step S1013, the processor 100 may count the number of false defects and determine whether the number of false defects is greater than or equal to the reference number.

In response to the fact that the number of false defects is greater than the reference number, the processor 100 may perform steps S1009 and S1011 described above.

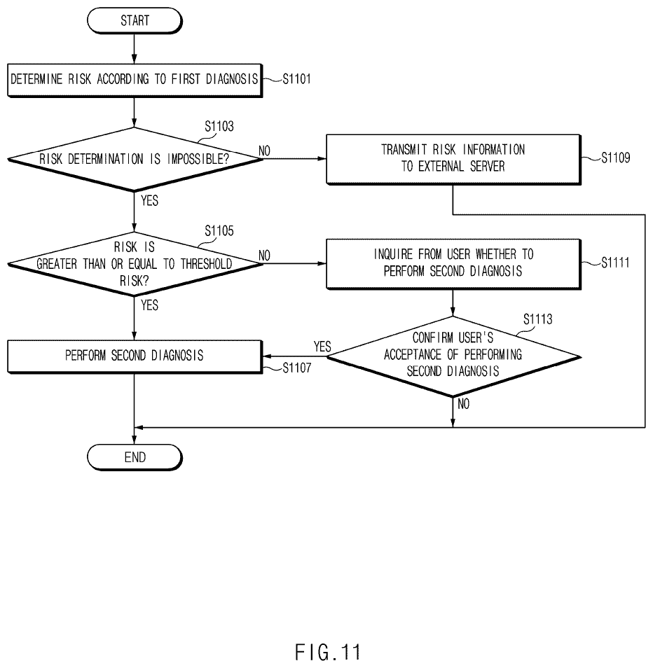

FIG. 11 is a flowchart illustrating a method of managing a battery according to another embodiment of the present disclosure. A method of managing a battery according to another embodiment of the present disclosure will be described with reference to FIG. 11 below.

In step S1101, the processor 100 may determine a risk according to the first diagnosis. The risk according to the first diagnosis may include at least one of a first risk indicating the degree of increase in the internal resistance of the battery 10, a second risk indicating the degree of increase in leakage current of the battery 10, and a third risk indicating the degree of decrease in SOH of the battery 10.

In steps S1103 and S1105, when it is possible to determine the risk, the processor 100 may compare the risk with a threshold risk.

In response to the fact that it is determined in step S1105 that the risk is higher than the threshold risk, the processor 100 may perform the second diagnosis in step S1107.

In addition, when it is determined that it is impossible to determine the risk, the risk information may be transmitted to an external server in step S1109. The risk information transmitted to the external server may be used as data to analyze why it is impossible to determine a risk through professional personnel.

In addition, in response to the fact that it is determined that the risk is less than the threshold risk, the processor 100 may inquire from the user whether to perform the second diagnosis in step S1111.

In step S1113, the processor 100 may perform step S1107 in response to confirming the user's acceptance of performing the second diagnosis.

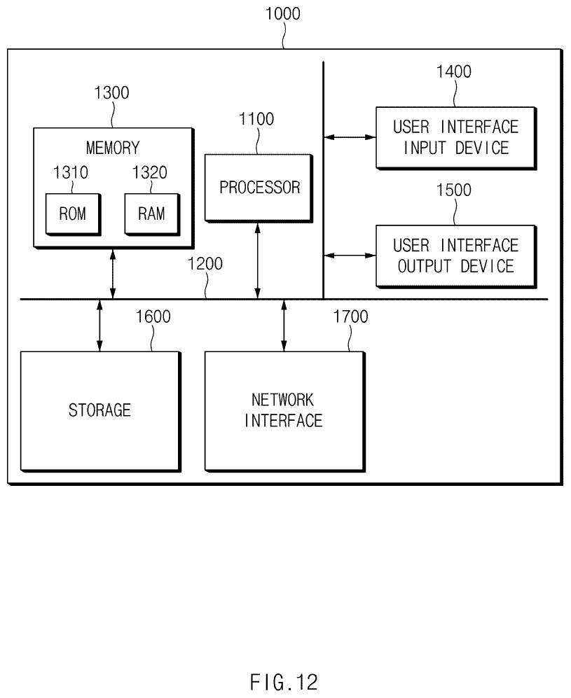

FIG. 12 is a diagram illustrating a computing system according to an embodiment of the present disclosure.

Referring to FIG. 12, a computing system 1000 may include at least one processor 1100, a memory 1300, a user interface input device 1400, a user interface output device 1500, storage 1600, and a network interface 1700 connected through a bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) and a RAM (Random Access Memory).

Accordingly, the processes of the method or algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM.

The exemplary storage medium is coupled to the processor 1100, and the processor 1100 may read information from the storage medium and may write information in the storage medium. In another method, the storage medium may be integrated with the processor 1100. The processor and the storage medium may reside in an application specific integrated circuit (ASIC). The ASIC may reside in a user terminal. In another method, the processor and the storage medium may reside in the user terminal as an individual component.

According to the embodiments of the present disclosure, it is possible to accurately determine whether the battery is defective by controlling the conditions for determining the abnormal state of the battery based on the first diagnosis of the battery.

In addition, according to the embodiments of the present disclosure, it is possible to accurately determine the internal resistance of the battery by adjusting the reference current during the fast charging period.

In addition, according to the embodiments of the present disclosure, it is possible to accurately determine the state of health of the battery by determining the state of health in the process of slow charging at a constant current.

In addition, according to the embodiments of the present disclosure, it is possible to accurately determine the leakage current of the battery by determining the leakage current after inactivating cell balancing in the parking and stopping state.

In addition, various effects that are directly or indirectly understood through the present disclosure may be provided.

Although exemplary embodiments of the present disclosure have been described for illustrative purposes, those skilled in the art will appreciate that various modifications, additions and substitutions are possible, without departing from the scope and spirit of the disclosure.

Therefore, the exemplary embodiments disclosed in the present disclosure are provided for the sake of descriptions, not limiting the technical concepts of the present disclosure, and it should be understood that such exemplary embodiments are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. An apparatus for battery management, the apparatus comprising:
a battery;
a voltage sensor configured to measure a voltage of the battery; and
a processor configured to:
determine an abnormal state of the battery during a first diagnosis period,
determine a diagnostic profile corresponding to a type of the abnormal state of the battery based on the detected abnormal state of the battery in a first diagnosis,
control a diagnostic condition of the battery based on the diagnostic profile, and
re-diagnose the abnormal state of the battery during a second diagnosis period while the diagnostic condition is controlled based on the diagnostic profile.

2. The apparatus of claim 1, wherein the processor is configured to detect at least one of an increase in an internal resistance of the battery, an increase in a leakage current of the battery, or a decrease in a state of health of the battery during the first diagnosis period.

3. The apparatus of claim 2, wherein the processor is configured to:
monitor a fast charging attempt of the battery based on the detection of the increase in the internal resistance of the battery as a determination result in the first diagnosis period; and
control the diagnostic condition when the fast charging attempt is present.

4. The apparatus of claim 3, wherein the processor is configured to control the diagnostic condition to increase a change rate of a reference current followed by the battery based on the fast charging attempt.

5. The apparatus of claim 2, wherein the processor is configured to control the diagnostic condition to inactivate a cell balancing operation of the battery based on the detection of the increase in the leakage current of the battery as a determination result in the first diagnosis period.

6. The apparatus of claim 2, wherein the processor is configured to:
monitor a slow charging attempt of the battery based on the detection of the decrease in the state of health of the battery as a determination result in the first diagnosis period; and
control the diagnostic condition based on the slow charging attempt.

7. The apparatus of claim 6, wherein the processor is configured to control the diagnostic condition to charge the battery at a constant current based on the slow charging attempt.

8. The apparatus of claim 7, wherein the processor is configured to:
determine a minimum charging current value based on a maximum charging power of a slow charger and a fully charged battery voltage, and
control slow charging based on the minimum charging current value.

9. The apparatus of claim 1, wherein the processor is configured to:
confirm a first measurement value indicating a degree of the abnormal state of the battery in the first diagnosis period;
confirm a second measurement value indicating the degree of the abnormal state of the battery in the second diagnosis period; and
determine a defective state of the battery based on magnitudes of the first measurement value and the second measurement value.

10. The apparatus of claim 9, wherein the processor is configured to:
determine the battery to be in a false defect state based on a magnitude ratio of the second measurement value to the first measurement value being outside a specified range; and
count a number of times the battery is determined to be in the false defect state, and guide a precise diagnosis of the battery based on that the counted number of times the false defect state is greater than or equal to a threshold number.

11. A method of battery management, the method comprising:
performing, by the processor, a first diagnosis to determine an abnormal state of a battery;
determining, by the processor, a diagnostic profile corresponding to a type of the abnormal state of the battery based on a detected abnormal state of the battery in the performing of the first diagnosis;
controlling a diagnostic condition of the battery based on the diagnostic profile, and
performing a second diagnosis of re-diagnosing the abnormal state of the battery while a diagnostic condition of the battery is controlled based on the diagnostic profile.

12. The method of claim 11, wherein the performing of the first diagnosis includes detecting at least one of an increase in an internal resistance of the battery, an increase in a leakage current of the battery, or a decrease in a state of health of the battery.

13. The method of claim 12, wherein the controlling of the diagnostic condition of the battery includes increasing a change rate of a reference current followed by the battery in a fast charging period based on the detection of the increase in the internal resistance of the battery through the first diagnosis.

14. The method of claim 12, wherein the controlling of the diagnostic condition of the battery includes inactivating a cell balancing operation of the battery based on the detection of the increase in the leakage current of the battery through the first diagnosis.

15. The method of claim 12, wherein the controlling of the diagnostic condition of the battery includes charging the battery at a constant current in a slow charging period of the battery based on the detection of the decrease in the state of health of the battery through the first diagnosis.

16. The method of claim 11, wherein the controlling of the diagnostic condition of the battery includes:
monitoring a driving state of a vehicle equipped with the battery; and
controlling the diagnostic condition of the battery based on detection of the driving state of the vehicle corresponding to the diagnostic profile.

17. The method of claim 11, wherein the performing of the second diagnosis further includes:
confirming a first measurement value indicating a degree of the abnormal state of the battery based on the first diagnosis;
confirming a second measurement value indicating the degree of the abnormal state of the battery in the second diagnosis; and
determining a defective state of the battery based on magnitudes of the first measurement value and the second measurement value.

18. The method of claim 17, further comprising:
determining the battery to be in a false defect state based on a magnitude ratio of the second measurement value to the first measurement value being outside a specified range; and
counting a number of times the battery is determined to be in the false defect state, and guiding a precise diagnosis of the battery based on that the counted number of times the false defect state is greater than or equal to a threshold number.

19. The method of claim 17, further comprising:
restricting entry into the second diagnosis when the first measurement value has a magnitude that cannot determine a risk of the battery.

20. The method of claim 17, further comprising:
confirming with a user of the vehicle whether the second diagnosis is entered based on that the first measurement value is greater than or equal to a threshold value.
